(19) United States
(12) Patent Application Publication
(10) Pub. No.: US 2012/0212259 A1
(43) Pub. Date: Aug. 23, 2012

(54) COMPARATOR OF A DIFFERENCE OF INPUT VOLTAGES WITH AT LEAST A THRESHOLD

(75) Inventors: Alberto Riva, Charvensod (IT); Giorgio Oddone, Villeneuve (IT); Domenico Attianese, Aosta (IT)

(73) Assignees: Dora S.p.A., Aosta (IT); STMicroelectronics S.r.l., Agrate Brianza (IT)

(21) Appl. No.: 13/398,694

(22) Filed: Feb. 16, 2012

(30) Foreign Application Priority Data
Feb. 17, 2011 (IT) MI2011A000234

(51) Int. Cl. H03K 5/22

(52) U.S. Cl. 327/89

(57) ABSTRACT

A comparator is configured to generate an output voltage representing the comparison between the absolute value of the difference between two input voltages with an adjustable reference voltage. The comparator includes an input differential amplifier, receiving the two input voltages and connected to an active load network controlled by a control voltage, a control circuit that generates the control voltage representing the adjustable reference voltage, and an output stage having a logic circuit configured to produce the output voltage of the comparator as a logic combination of the output voltages of the differential amplifier.

### BACKGROUND

1. Technical Field

This disclosure relates in general to electronic voltage comparators and more particularly to a comparator of a difference of input voltages with at least a threshold.

2. Description of the Related Art

In electronic devices it may be desired to compare two analog voltages for generating logic signals such to allow to a digital part of the device to take certain decisions depending on the result of the comparison. In particular, it may be desired to generate a logic signal VOUT when the absolute value of the difference between two input voltages VIN1 and VIN2 surpasses a reference voltage VREF, customizable in a fixed range, that is

VOUT=|VIN1−VIN2>VREF

being

VREF∈[VREFₘᵢₙ,VREF_{MAX}].

The electrical scheme of a known comparator is shown in FIG. 1 and substantially corresponds to that disclosed in U.S. Pat. No. 5,517,134. The operational amplifier OTA1 imposes on the resistor R a voltage equal to the reference voltage VREF and the current VREF/R is mirrored on the two resistors R in series. The operational amplifier OTA2 sets an input voltage VIN2 at the middle point of the series of resistors R, thus the comparators COMP1 and COMP2 compare the other input voltage VIN1 with the voltages VIN2+VREF and VIN2−VREF, respectively, and, if at least an output of the two comparators assumes a high logic value, a high logic signal VOUT is generated for flagging that the absolute value of the difference between the two input voltages VIN1 and VIN2 exceeds the reference voltage VREF.

This solution has the following limitations:
it has a high input offset, because many components contribute to it (the operational amplifiers OTA, the comparators, the current mirror and the resistors);
does not work for voltages VIN1 or VIN2 close to 0V;
has a large area occupation because of the presence of two compensation capacitances for the operational amplifiers;
has a high current consumption because numerous components are used.

Another known architecture of a comparator is shown in FIG. 2 and is disclosed in the U.S. Pat. No. 6,605,964. It uses two differential stages with degeneration resistances, the output nodes of which are connected in common to an active load ACTIVE LOAD. The output voltage VOUT is made available on an output branch of the active load. Connected to a differential amplifier there are the ground signal and the signal VREF, or the signals VREFL and VREFH such that VREFH−VREFL=VREF. The input signals VIN1 and VIN2 are applied to the other differential amplifier such that the greatest of the two signals is always input to the same MOS of the differential amplifier and the smallest signal is always connected to the other MOS of the differential amplifier. In order to do so, a selector of the greatest of the two signals is required, that may be a comparator COMP, for indicating which one of the input voltages VIN1 and VIN2 is the greatest.

The output branches of the differential amplifiers are connected in common to make the current variation due to the unbalancing of one differential stage be wholly absorbed by the other differential stage when an unbalancing of the same amount and of the correct sign is applied thereto. In this way, the currents flowing through the two branches of the active load are identical and the output is thus in a transition zone: by increasing or decreasing one of the signals of the differential amplifiers the output voltage VOUT switches high or low.

The degeneration resistances of the differential amplifiers enhance linearity of the difference of the output currents of the two branches of each differential amplifier in respect to the difference between the input voltages applied to the differential amplifier itself. This expedient allows to increase the functioning range of the circuit in respect to the voltage values that the signal VREF may assume.

According to an alternative embodiment, instead of switching the input voltages VIN1 and VIN2, it would be possible to obtain the same result using two equivalent structures, each composed of two differential stages and an active load, with the respective output voltages combined as a logic OR and in which there is a first structure with a pair of inputs inverted in respect to the other structure.

However this would imply a larger silicon area occupation.

On the other hand, the approach of using two architectures with outputs combined in a logic OR can be used when the comparator must work even when the reference voltages VREF are close to 0 V. In these conditions, the single structure comparator of FIG. 2 cannot work because the comparator COMP needs a hysteresis on its input signals for preventing its output from oscillating because of noise that is always present in electronic circuits.

By resuming, the comparator of FIG. 2 has the following advantages in respect to the comparator of FIG. 1:
reduced offset of the input voltage because of the fewer components that make the comparator;
correct functioning also for VIN1 and VIN2 close to 0 V;
reduced area consumption because there is no compensation capacitance and a reduced number of used blocks;
reduced current consumption (smaller number of used blocks).

Several drawbacks are:
need of switching the inputs of one of the two differential amplifiers for comparing of the absolute value: this operation in general may be difficult because it may cause spikes on the inputs and because switching the inputs takes a relatively long time;
impossibility of functioning for voltages VREF close to 0V because of the use of a comparator for switching the inputs that has a hysteresis such to prevent oscillations when the inputs have voltages very close between them;
relatively large current consumption and area occupation due to the presence of the comparator and of the system for switching the inputs.

A comparator not affected by the above drawbacks that limit the performances of the known architectures of FIGS. 1 and 2 would be desirable.

### BRIEF SUMMARY

A way of performing voltage comparison and selection of the greatest and related circuit architectures have been found that obviates to the limitations of the known architectures discussed above.

A comparator according to one embodiment of this disclosure is adapted to generate an output voltage representing the comparison between the absolute value of the difference between two input voltages with an adjustable reference voltage and includes a first input differential amplifier receiving the two input voltages and connected to an active load network controlled by a control voltage, a control circuit that generates the control voltage representing the adjustable reference voltage, and an output stage having at least a logic circuit adapted to produce the output voltage of the comparator as a logic combination of the output voltages of the first differential amplifier.

According to an embodiment, the control circuit is substantially equal to the input differential amplifier and is controlled by a differential pair of voltages representing the adjustable reference voltage.

All the architectures of the input differential amplifiers and of the control circuits may be dually realized in a “folded” topology.

### BRIEF DESCRIPTION OF THE SEVERAL VIEWS OF THE DRAWINGS

FIG. 1 depicts a known comparator of the absolute value of a difference of input voltages VIN1 and VIN2 with a threshold VREF.

FIG. 2 depicts another known comparator of the absolute value of a difference of input voltages VIN1 and VIN2 with a threshold VREF.

FIG. 3 depicts an input differential amplifier and a control circuit of an embodiment of the comparator of the absolute value of a difference of input voltages VIN1 and VIN2 with a threshold VREF of this disclosure.

FIG. 4 depicts an output stage of an embodiment of the comparator of the absolute value of a difference of input voltages VIN1 and VIN2 with a threshold VREF of this disclosure.

FIGS. 5 and 6 are graphs of electrical characteristics of the comparator depicted in FIGS. 3 and 4.

FIG. 7 depicts an output stage of a hysteresis comparator of a difference between input voltages VIN1 and VIN2 with a hysteresis threshold VREF, of this disclosure.

FIG. 8 is a graph that illustrates the functioning of the output stage of FIG. 7 in function of VIN1 with VREFH−VREFL equal to 100 mV.

FIG. 9 depicts an input differential amplifier and a control circuit of another embodiment of the comparator of the absolute value of the sum of a difference of input voltages VIN1 and VIN2 with a threshold VTHL−VTHH with the value of the difference VREFH−VREFL that must be positive, of this disclosure.

FIG. 10 shows an input differential amplifier and a control circuit according to yet another embodiment of the comparator of the absolute value of a difference of input voltages VIN1 and VIN2 with a threshold VREFH−VREFL having a pair of identical cascode, of this disclosure.

FIG. 11 depicts an input amplifier and a control circuit according to an embodiment of the comparator, in “folded” topology, of the absolute value of a difference of input voltages VIN1 and VIN2 with the absolute value of the difference VREFH−VREFL, of this disclosure.

FIG. 12 depicts an output stage of the comparator with “folded” topology, of the absolute value of a difference of input voltages VIN1 and VIN2 with the absolute value of a threshold VREF, of this disclosure.

FIG. 13 is an exemplary graph that illustrates the functioning of the output stage depicted in FIG. 12 used in conjuction with the “folded” topology in FIG. 11.

FIG. 14 depicts an output stage of a hysteresis comparator with “folded” topology of a difference of input voltages VIN1 and VIN2 with a hysteresis threshold |VREF|.

FIG. 15 depicts an alternative input differential amplifier and related control circuit of an embodiment of the comparator of a difference of input voltages VIN1 and VIN2 with a threshold VREF of this disclosure.

FIG. 16 depicts the analog part of an output stage of an embodiment of the comparator of a difference of input voltages VIN1 and VIN2 with a threshold VREF of this disclosure.

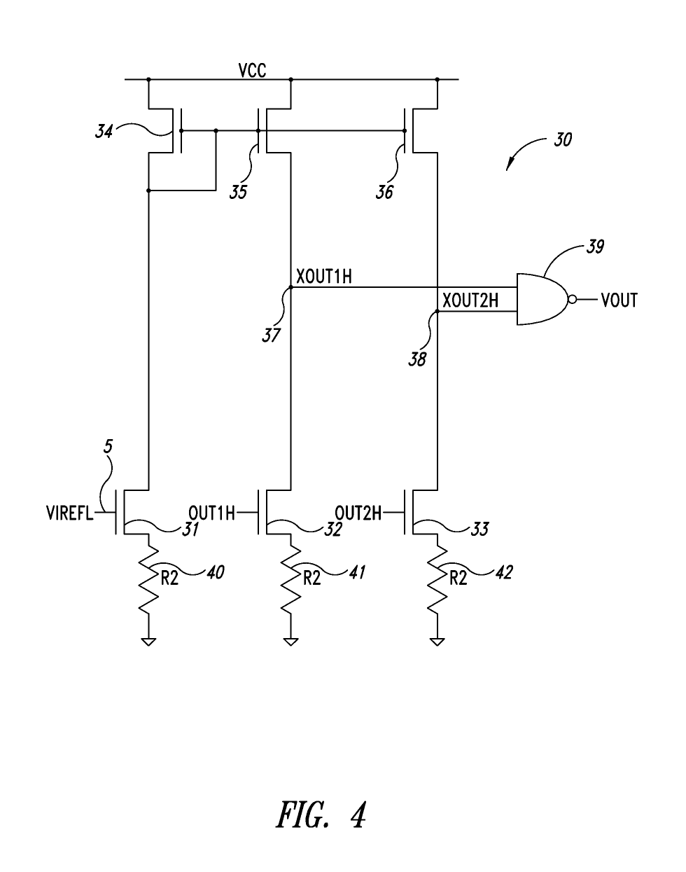

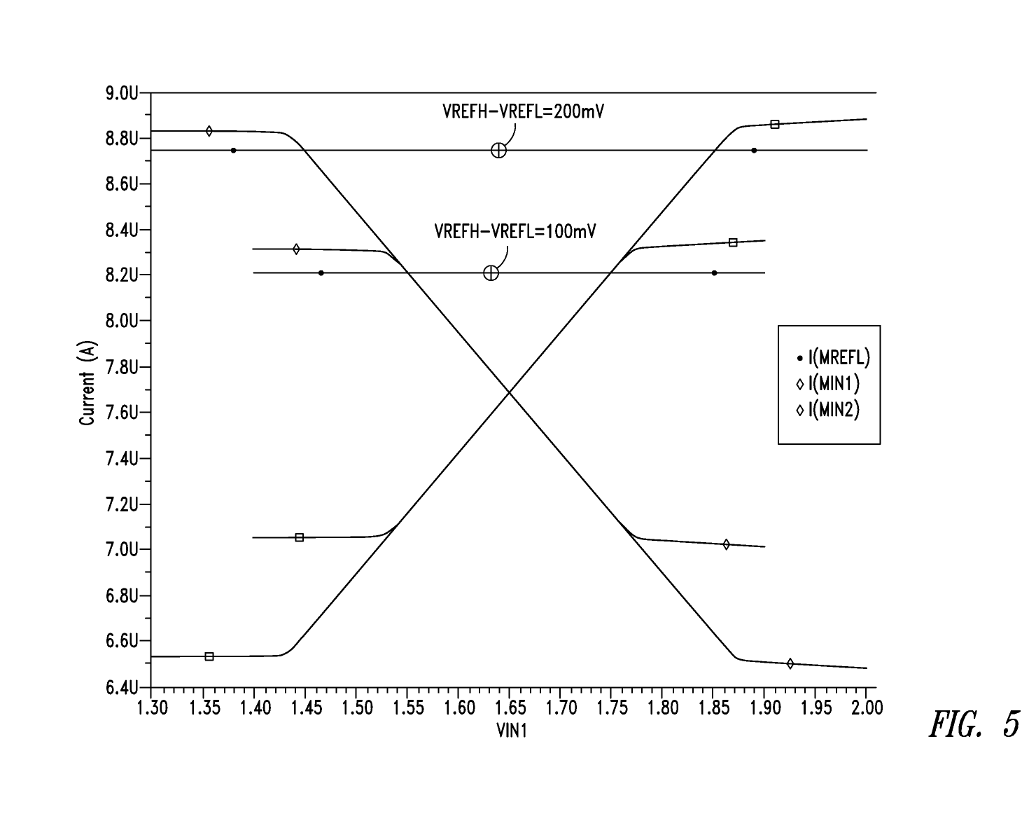

Figures from 17 to 20 depict further alternative embodiments of the output stages of FIGS. 4, 7, 12 and 14 comprising cascode current mirrors.

### DETAILED DESCRIPTION

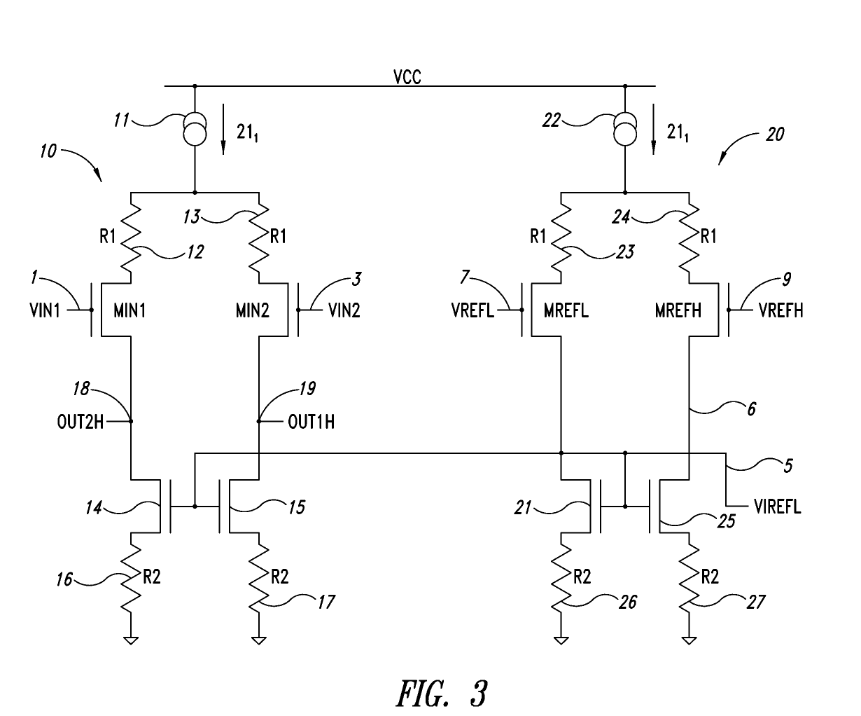

A comparator of the absolute value of the difference between two voltages VIN1 and VIN2 with a reference VREF according to one embodiment of the present disclosure comprises first and second input voltage terminals 1, 3; a control voltage terminal 5; first and second reference voltage terminals 7, 9; an input differential amplifier 10; a control circuit 20; and an output stage 30. According to an embodiment, the input differential amplifier 10 and control circuit 20 are shown in FIG. 3, and the output stage 30 is shown in FIG. 4.

The input differential amplifier 10 includes a first current source 11; first and second degeneration resistors 12, 13; a differential pair of PMOS input transistors MIN1, MIN2; first and second NMOS load transistors 14, 15; and third and fourth degeneration resistors 16, 17, all coupled between first and second supply terminals VCC, ground. The first and second degeneration resistances respectively couple the sources of the input transistors MIN1, MIN2 to the first current source and the third and fourth degeneration resistances respectively couple the sources of the load transistors 14, 15 to ground. The control terminals of the input transistors are respectively coupled to the first and second input terminals to receive the first and second input voltages VIN1 and VIN2. The drains of the input transistors MIN1, MIN2 are coupled to the drains of the load transistors 14, 15 by first and second intermediate nodes 18, 19, respectively, at which are produced first and second intermediate voltages OUT2H, OUT1H, respectively. The first and second degeneration resistors 12, 13 each have a substantially identical first resistance R1 and the third and fourth degeneration resistors 16, 17 each have a substantially identical second resistance R2.

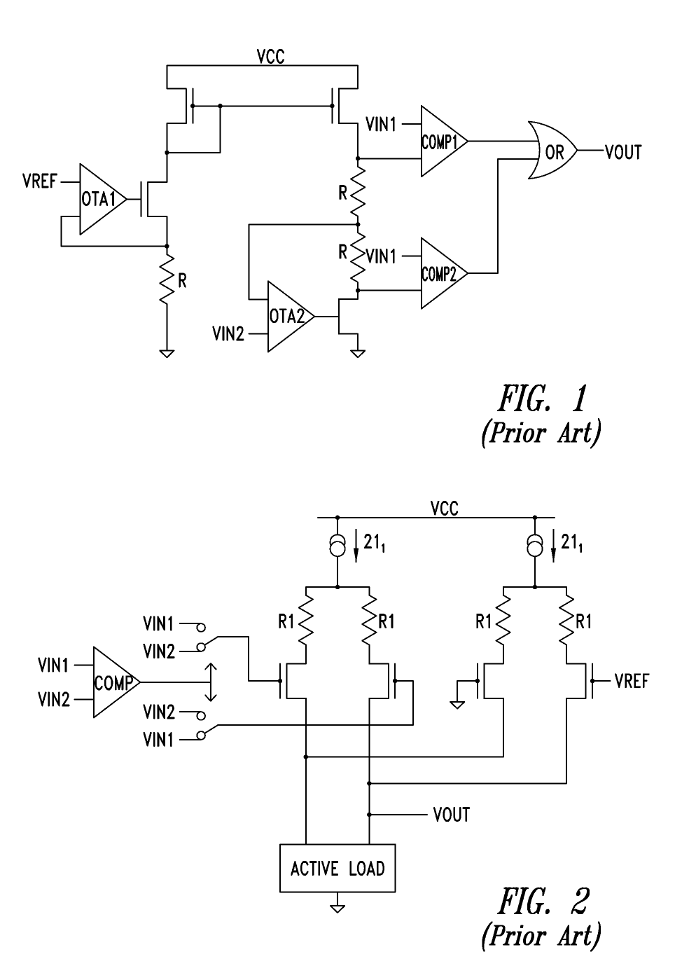

Differently from the known comparator of FIG. 2, the load transistors have respective gates coupled to the control voltage terminal 5, which is configured to provide a control voltage VIREFL generated by the control circuit 20 represented on the right side on FIG. 3. This control circuit 20 is a second differential amplifier that is almost identical to the input differential amplifier 10 and has at least a diode-connected third NMOS load transistor 21, substantially identical to the load transistors 14, 15 of the input differential amplifier 10. The control circuit 20 further includes a second current source 22 having the same current of 11; fifth and sixth degeneration resistors 23, 24 having substantially the first resistance R1; a second differential pair of PMOS input transistors MREFL, MREFH; a fourth NMOS load transistors 25; and seventh and eighth degeneration resistors 26, 27, all coupled between VCC and ground. The fifth and sixth degeneration resistances respectively couple the sources of the input transistors MREFL, MREFH to the second current source 22 and the seventh and eighth degeneration resistances 26, 27 respectively couple the sources of the load transistors 21, 25 to ground. The control terminals of the input transistors MREFL, MREFH are respectively coupled to the reference voltage terminals 6, 7 which are coupled to receive differential voltages VREFL and VREFH that represent the reference voltage VREF. The drain of the input transistors MREFL is coupled to the drain of the load transistor by the control voltage terminal 5, on which the control voltage VIREFL is available, having a level corresponding to the differential voltages VREFL and VREFH that represent the reference voltage VREF with which the absolute value of the difference of the two input voltage is to be compared.

In the exemplary embodiment of FIG. 3, the control circuit 20 is almost identical to the input differential amplifier 10 and controls the active load transistors 14, 15 of the input differential amplifier 10 with the same control voltage VIREFL of the diode-connected transistor 21.

The input differential amplifier 10 and control circuit 20 effectively compare output currents through the branches of the input differential amplifier 10 with the reference current that flows through the diode-connected MOS transistor 21 controlled by the voltage VREFL.

With this technique, only one of the two currents of the input differential amplifier 10 exceeds the reference current given by the control circuit 20 when the unbalancing |VIN2−VIN1| is greater than VREFH−VREFL, which is the desired function.

The output stage 30 of FIG. 4 is used to amplify the voltages OUT2H and OUT1H of the first stage, and is realized such to not introduce systematic offsets on the output. For this reason, the output stage 30 has transistors 31, 32, 33 substantially identical to the load transistors 14, 15, 21, 25 and controlled by the control voltage VIREFL and by the voltages OUT1H and OUT2H, respectively. The output stage 30 further includes a current mirror having first, second, and third mirror transistors 34, 35, 36 having respective sources coupled to one another and to the supply voltage terminal Vcc and respective gates coupled to one another. The first mirror transistor 34 is a diode-connected transistor having its drain and gate coupled to the drain of the transistor 31, the second mirror transistor 35 has its drain coupled to the drain of the transistor 32 at a third intermediate node 37, and the third mirror transistor 36 has its drain coupled to the drain of the transistor 33 at a fourth intermediate node 38. The output stage 30 also includes a NAND gate 39 having first and second inputs coupled to the third and fourth intermediate nodes 37, 38 and an output at which is produced the output voltage VOUT which reflects the absolute value of the difference between two voltages VIN1 and VIN2 with a reference VREF. The output stage 30 also includes degeneration resistors 40, 41, 42 coupled between ground and the transistors 31, 32, 33, respectively.

When the unbalancing between the input voltages VIN1 and VIN2 equals the unbalancing between VREFH and VREFL and the common mode voltages applied to the two differential amplifiers 10, 20 are equal to each other, the voltages of the corresponding nodes 18, 19 of the input differential amplifier 10 and the voltages of the node 6 and of the control terminal 5 of the control circuit are equal to each other, respectively.

The output VOUT provided by the NAND gate 39 of the comparator is a logic NAND of signals XOUT1H and XOUT2H produced at the third and fourth intermediate nodes 37, 38. Indeed, if at least one of the two signals (XOUT1H or XOUT2H) is null, this means that the absolute value of the difference between voltages VIN2 and VIN1 is greater than the difference VREFH−VREFL.

In order to reduce systematic errors that arise when the common mode voltages between the pair VIN1 and VIN2 and the pair VREFH and VREFL are different, it is possible to use cascodes for the MOS transistors of the differentials 10, 20, such that the drain-source voltages of the MOS transistors between the two differentials are kept symmetrical. To this end, also the variation of the thresholds of the MOS transistors of the differentials, which is due to the body effect, has been eliminated because of the body effect, by biasing the body of the MOS transistors of the input differential amplifier 10 and of the control differential amplifier 20 at the voltage present between the two resistances R1 of the respective differentials. Also in the output stage 20, cascodes may be used such to minimize the dependence of the switching voltage in respect to the supply voltage VCC and the “mirroring” errors due to the different drain-source voltages on the various MOS transistors.

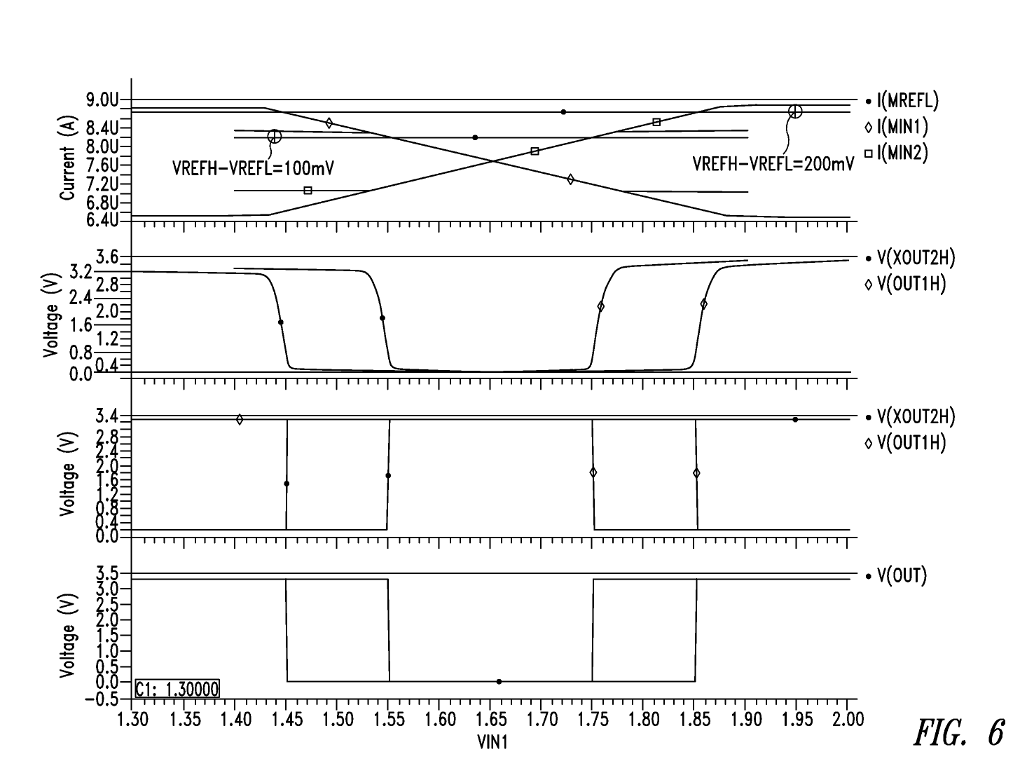

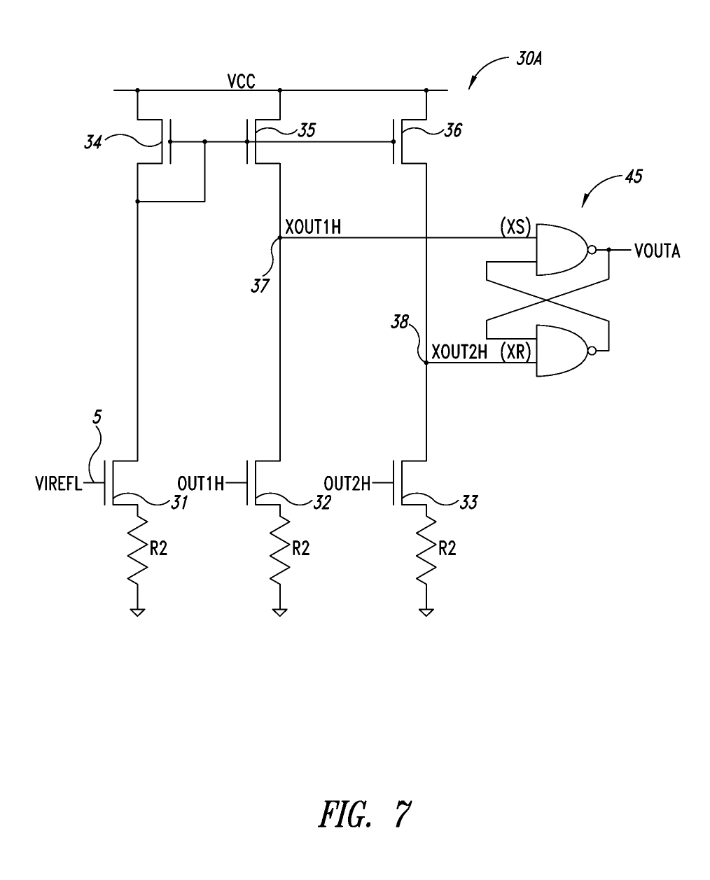

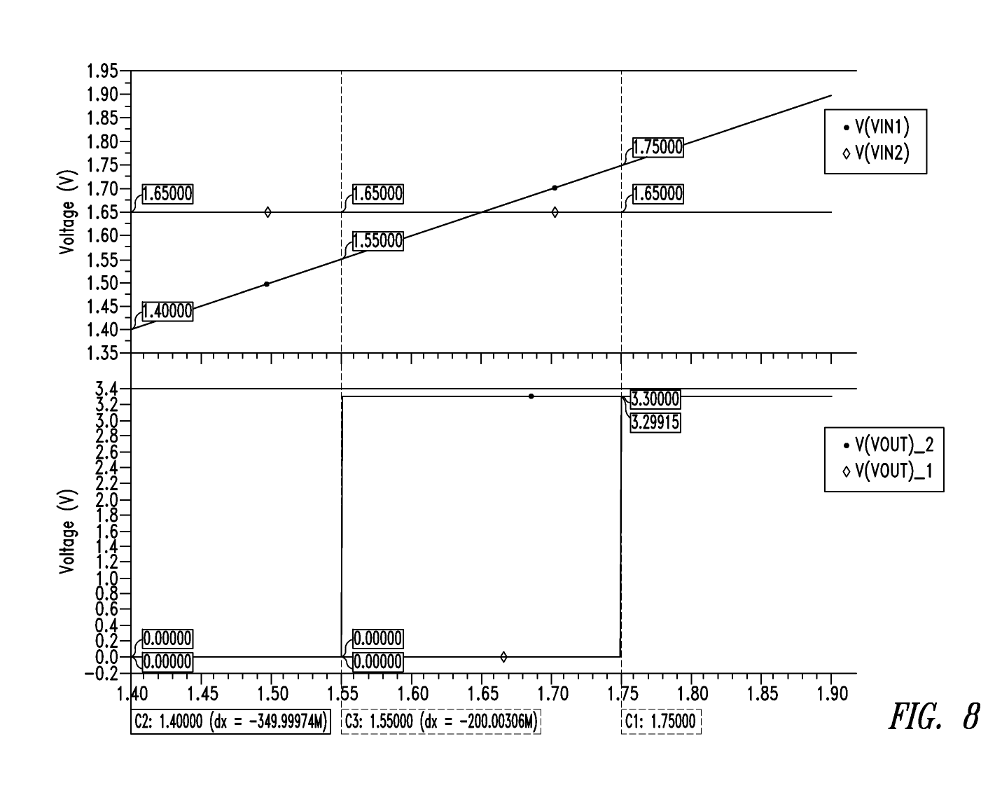

FIGS. 5 and 6 depict graphs of the main signals of circuits of FIGS. 3 and 4 in function of VIN1 for an input voltage VIN2 about equal to 1.65V and for two different values of VREFH−VREFL equal to 100 mV and to 200 mV.

The currents through the two branches of the input differential amplifier 10 tend to equalize the currents in the control circuit 20 when the difference between the absolute value of the input voltages approaches the difference VREFH−VREFL. As a consequence, the output voltages OUT1H and OUT2H have a sigmoidal shape with switching thresholds approximately corresponding to the voltage values VIN1 at which the absolute value of the difference VIN1−VIN2 exceeds VREFH−VREFL.

The output stage 30 of FIG. 4 generates the signals XOUT1H and XOUT2H that are “straightened” (and inverted) replicas of the voltages OUT1H and OUT2H, adapted to be combined by the logic circuit (that in the exemplary case is the NAND gate 39) for generating the output voltage VOUT, that assumes a high logic value when the absolute value of the difference between the input voltages exceeds VREFH−VREFL.

The fact that the control voltage VIREFL is generated by the control circuit in function of the differential pair of reference voltages VREFH and VREFL, makes programmable the switching threshold of the output voltage VOUT, compensating at the same time any eventual nonlinearity of the input differential amplifier 10. Moreover the output stage 30 makes sharper the switching edge of the output voltage, by minimizing the systematic error in the definition of the switching threshold.

The illustrated architecture of this disclosure has all advantages of the known solution of FIG. 2 and further ensures:
a halved offset of the input voltage with the same silicon area occupation, because the comparator of FIGS. 3 and 4 does not include the input comparator COMP of FIG. 2;
it functions correctly also for VIN1 and VIN2 close to 0V without the need of replicating the structure;
it functions also for voltages VREF close to 0V;
switching of the inputs of one of the two differentials 10, 20 is prevented: there is not any problem of spikes generation and of timing of the switching;
reduced current consumption because there is not the input comparator COMP of FIG. 2.

The proposed architecture may be used as a hysteresis comparator by using the output stage 30A as shown in FIG. 7, composed of an SR latch 45 in the place of a NAND gate 39 of FIG. 4. By applying to the input differential amplifier 10 a signal to be compared VIN1 with a reference VIN2, the difference VREFH−VREFL representing the desired hysteresis, the output voltage VOUTA of FIG. 7 will represent the result of the comparison between VIN1 and VIN2 with the hysteresis VREFH−VREFL centered on VIN2.

The functioning of the above described hysteresis comparator, for VREFH−VREFL equal to 100 mV, is depicted in FIG. 8.

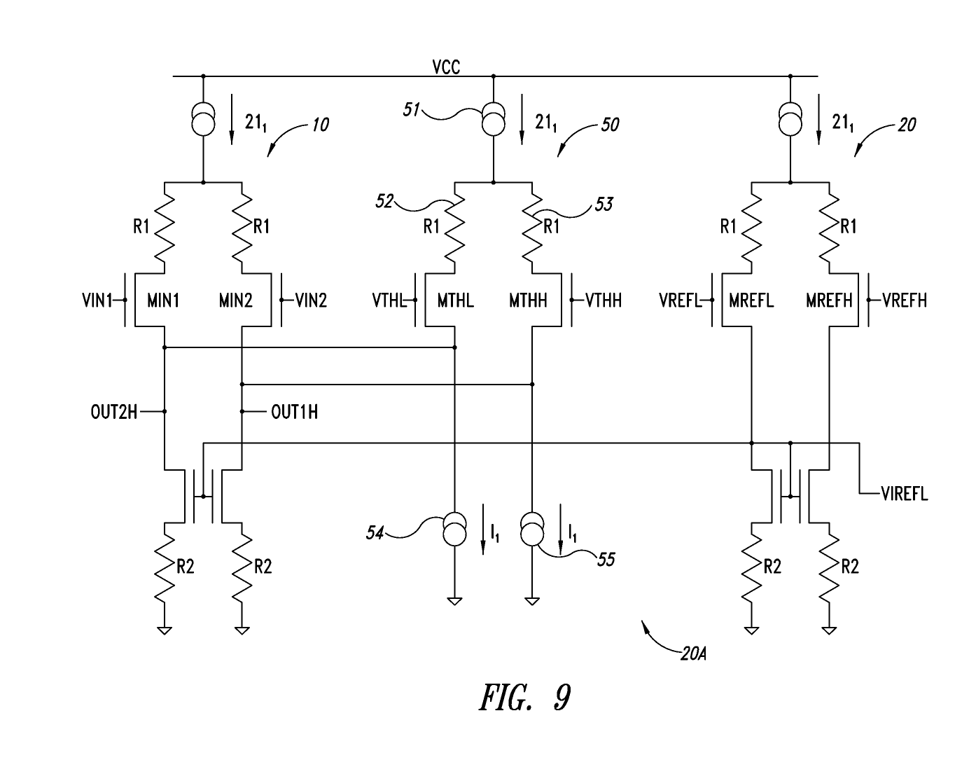

If, besides the hysteresis, a further adjustable switching threshold VTHH−VTHL, not depending on the output stage, between VIN1 and VIN2 is desired, it is possible to realize the control circuit 20A as shown in FIG. 9 and the output stage 30A as shown in FIG. 7. The control circuit 20A includes the differential control circuit 20 of

FIG. 3 and a further differential amplifier 50 that is coupled to the input differential amplifier 10. The further differential amplifier 50 includes a third current source 51; degeneration resistors 52, 53; a differential pair of PMOS input transistors MTHL, MTHH; and current generators 54, 55, all coupled between VCC and ground. The resistors 52, 53 respectively couple the sources of the input transistors MTHL, MTHH to the third current source 51 and the current sources 54, 55 respectively couple the drains of the transistors MTHL, MTHH to ground. The drains of the input transistors MTHL, MTHH are coupled to the drains of the input transistors MIN1, MIN2, respectively.

The further differential amplifier 50 of the control circuit 20A, biased by the current generator 51 with a current 21 substantially equal to the bias current of the input differential amplifier 10, is controlled by the differential pair of voltages VTHH and VTHL that represents the further adjustable threshold VTHH−VTHL. The two bias current generators 54, 55 prevent the bias currents through the two branches of the further differential amplifier 50 from flowing through the load transistors 14, 15 of the input differential amplifier 10. In this way it is possible to obtain a positive hysteresis and a negative hysteresis of different value without using feedback loops of the output voltage, that could limit the variation range of the input voltages VIN1 and VIN2 and that could limit also the minimum value of the usable hysteresis thresholds. Indeed, during the switching of the signals connected to the differentials, if the band-pass is not limited with filters, in order to be fast, and unless particular solutions are envisaged, there are spikes on the various nodes that, for thresholds with small hysteresis, may erroneously let the output of the comparator bounce back immediately, thus complicating the design of the whole device.

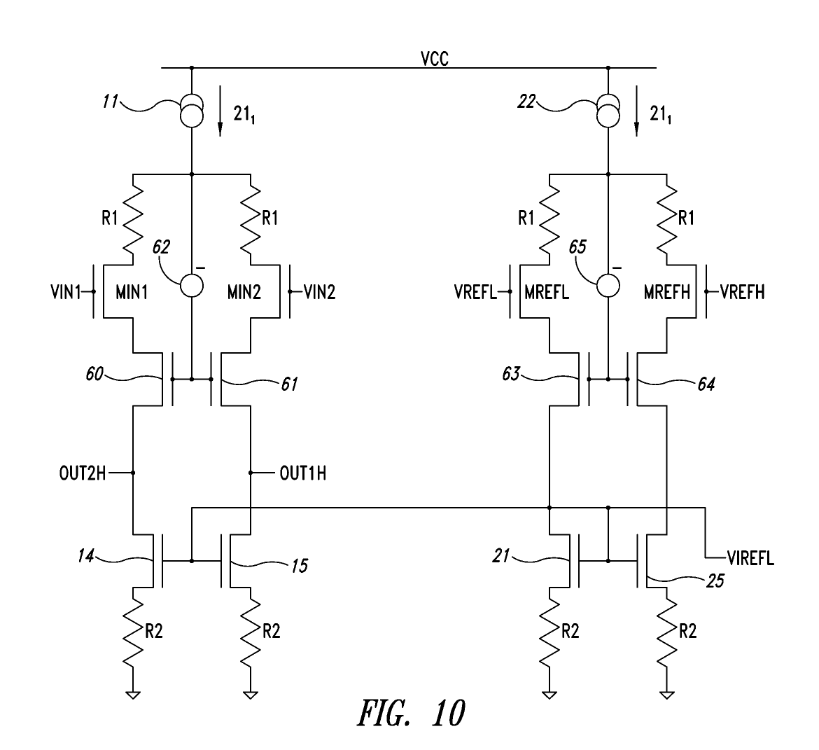

In order to reduce the dependency of the voltages OUT1H and OUT2H from the common mode voltage (VIN1+VIN2)/2 of the input signals and the common mode voltage (VREFH+VREFL)/2 of the differential pair of reference voltages, it is possible to connect the differential pair of input transistors MIN1, MIN2 to the load transistors 14, 15 through a pair of substantially identical cascode transistors 60, 61, as shown in FIG. 10 The cascode transistors 60, 61 are controlled by a constant voltage generator 62 coupled between the current source 11 and the gates of the cascode transistors 60, 61. Similarly, the input transistors MREFL, MREFH can be coupled to the load transistors 21, 25 through another pair of substantially identical cascode transistors 63, 64, which are controlled by another constant voltage generator 65 coupled between the current source 22 and the gates of the cascode transistors 63, 64. The functioning of the architecture of FIG. 10 will be immediately clear for any skilled person in the light of what has been said above referring to the architecture of FIG. 3. The architecture of FIG. 10 is connectable to a same output stage 30 used for the architecture of FIG. 3.

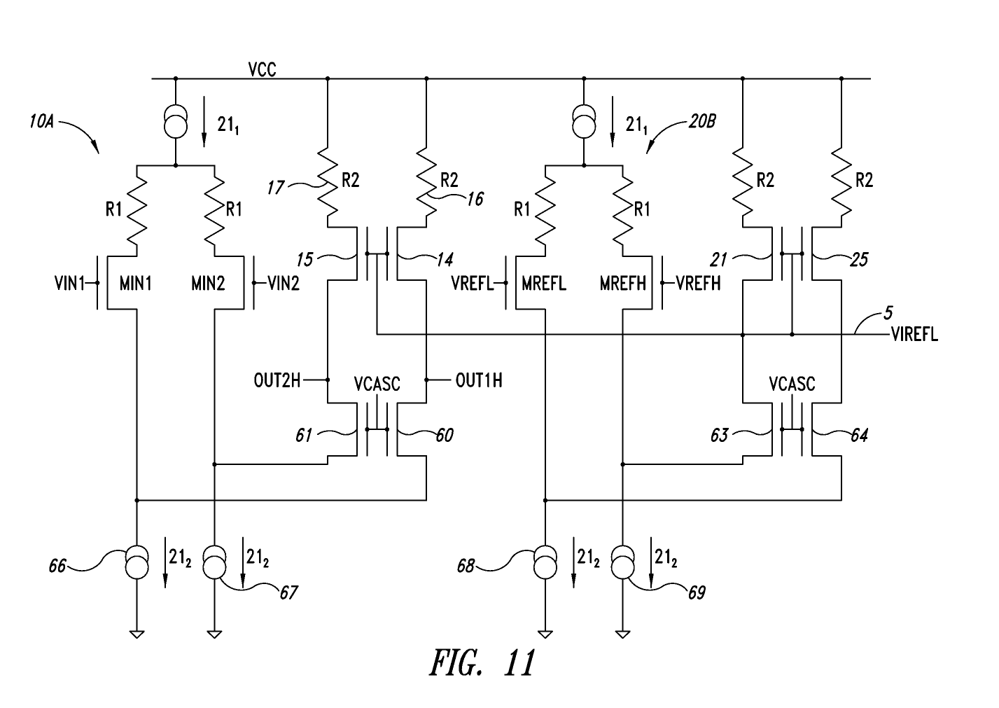

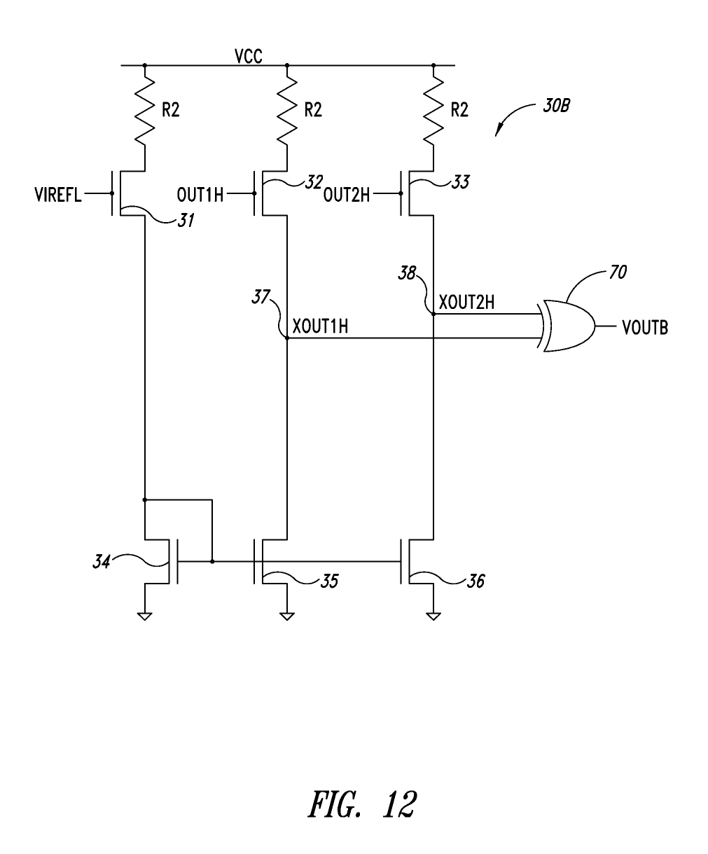

The architectures of this disclosure illustrated in FIGS. 11 and 12 allow to generate an output voltage VOUT representative of the comparison between the absolute value of the difference of input voltages VIN1 and VIN2 and of the absolute values of the difference between the reference voltages VREFH and VREFL, that is:

VOUT=(|VIN1−VIN2|>|VREFH−VREFL|).

In order to realize this function, both the input differential amplifier 10A as well as the differential amplifier 20B of the control circuit are realized according to a “folded” topology. The differential amplifier 10A of FIG. 11 differs from the differential amplifier 10 of FIG. 3 in that the load transistors 14, 15 are respectively coupled between the input transistors MIN1, MIN2 and the upper supply voltage Vcc instead of the ground potential, as in the embodiment of FIG. 3. Similarly, the load transistors 21, 25 of the differential amplifier 20B are coupled between the differential transistors MREFL, MREFH and Vcc instead of ground. This “folded” topology also comprises the cascode transistors 60, 61 controlled in saturation by a voltage VCASC and further bias current generators 66, 67, and the cascode transistors 63, 64 controlled in saturation by the voltage VCASC and further bias current generators 68, 69. The output voltage VOUTB will be preferably realized using the output stage 30B shown in FIG. 12, which includes an XOR gate 70 as a logic circuit that generates the output voltage VOUT as the logical XOR of the voltages XOUT1H and XOUT2H.

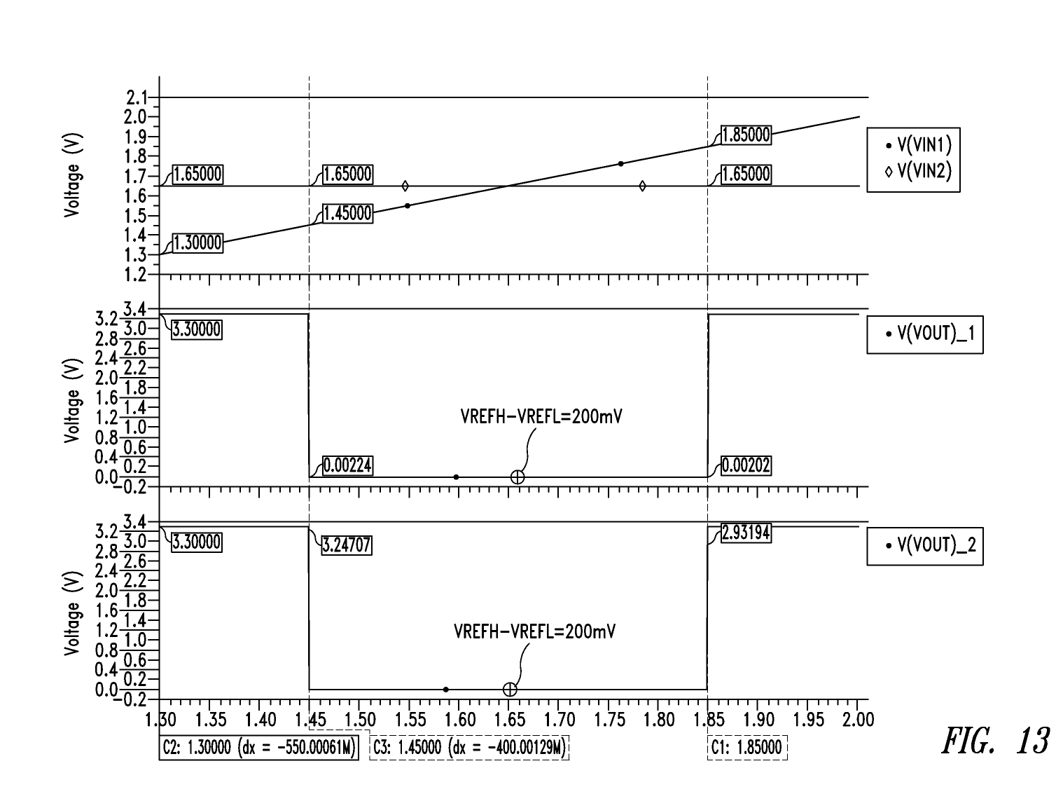

The functioning of the architecture of the comparator depicted in FIGS. 11 and 12 is shown in FIG. 13.

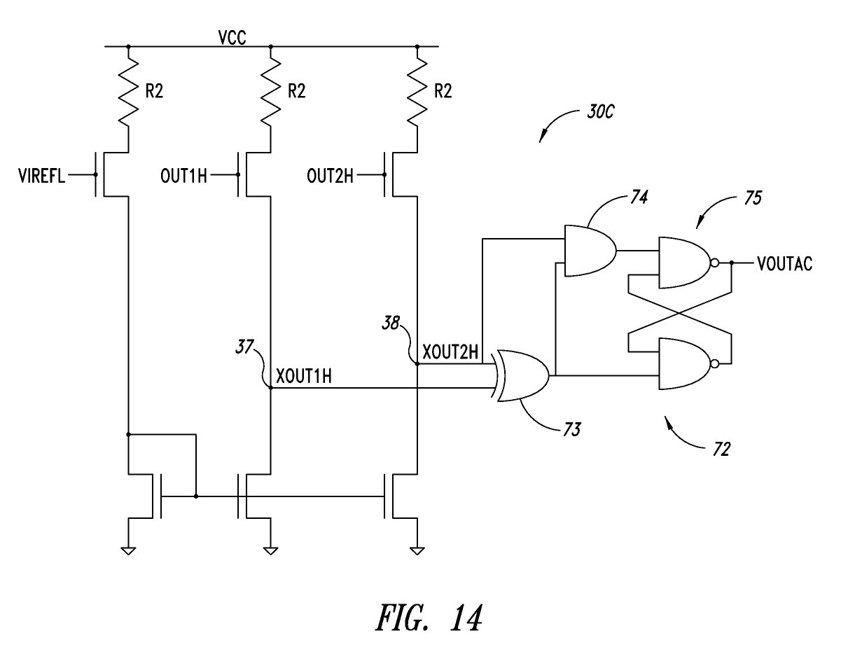

The just described comparator may be transformed in a comparator with hysteresis by using the output stage 30C of FIG. 14 instead of that of FIG, 12, similarly to what has been stated above referring to FIG. 7. The output stage 30C includes a logic circuit 72 that includes an XOR gate 73 having inputs respectively coupled to the intermediate nodes 37, 38, an AND 74 gate having inputs respectively coupled to the intermediate node 38 and the output of the XOR gate 73, and an SR flip-flop 75 having inputs respectively coupled to the outputs of the XOR gate 73 and AND gate 74 and an output at which the output signal VOUTC is produced. With the output stage 30C of FIG. 14 the comparator functions in the same way both with a positive or a negative difference VREFH−VREFL.

Other embodiments of the comparator of this disclosure may be obtained with “folded” type architectures corresponding to those of FIGS. 9 and 10, using one of the output stages of FIGS. 12 and 14.

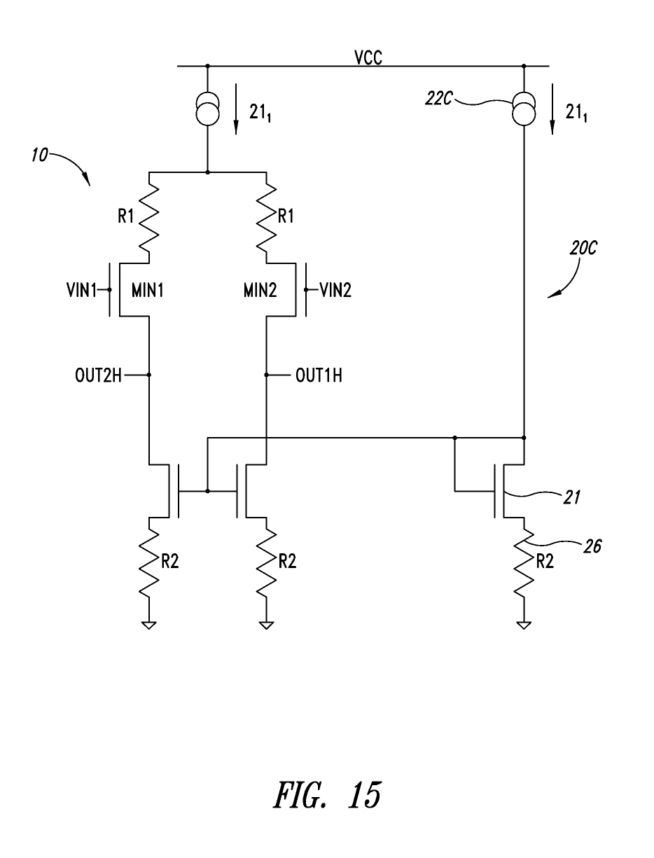

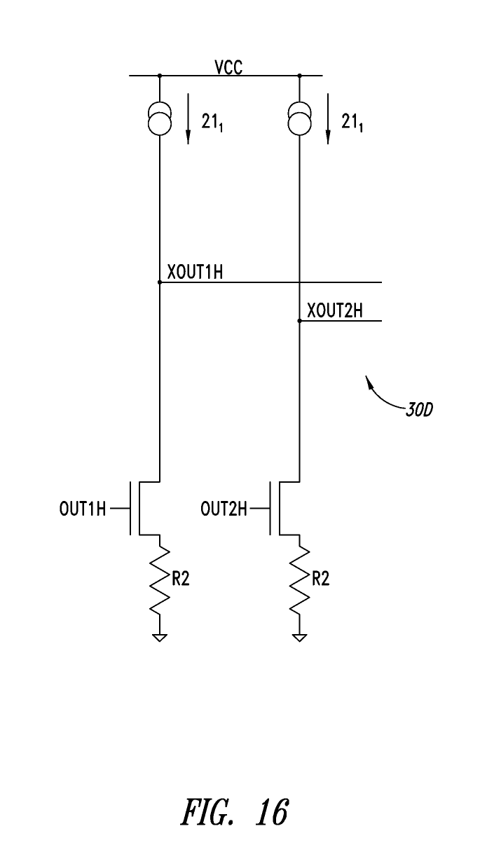

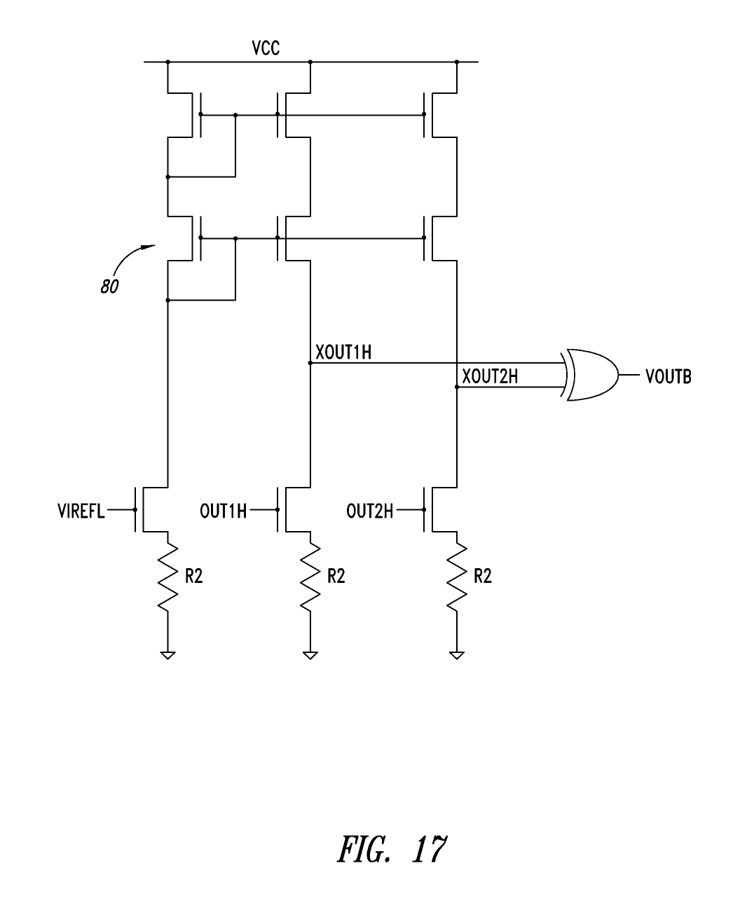

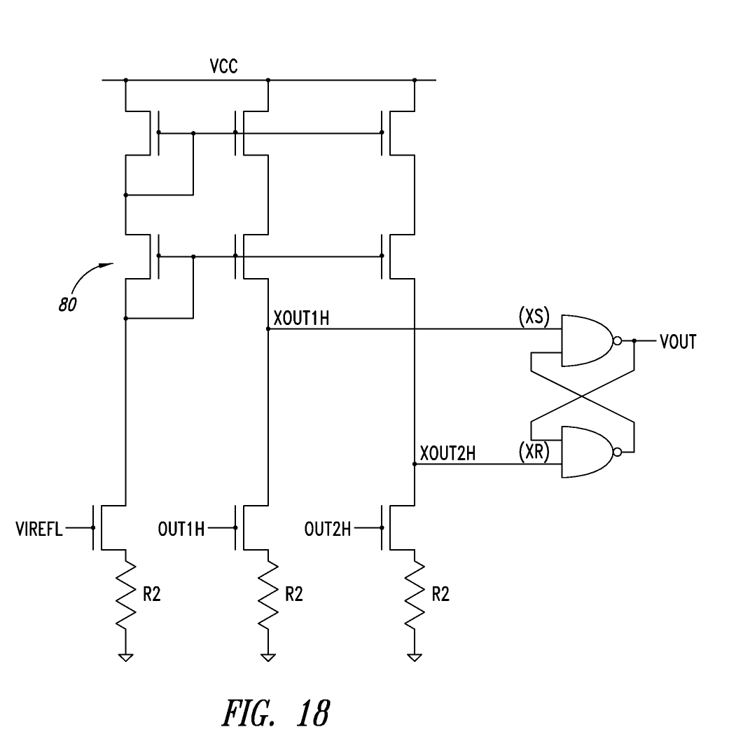

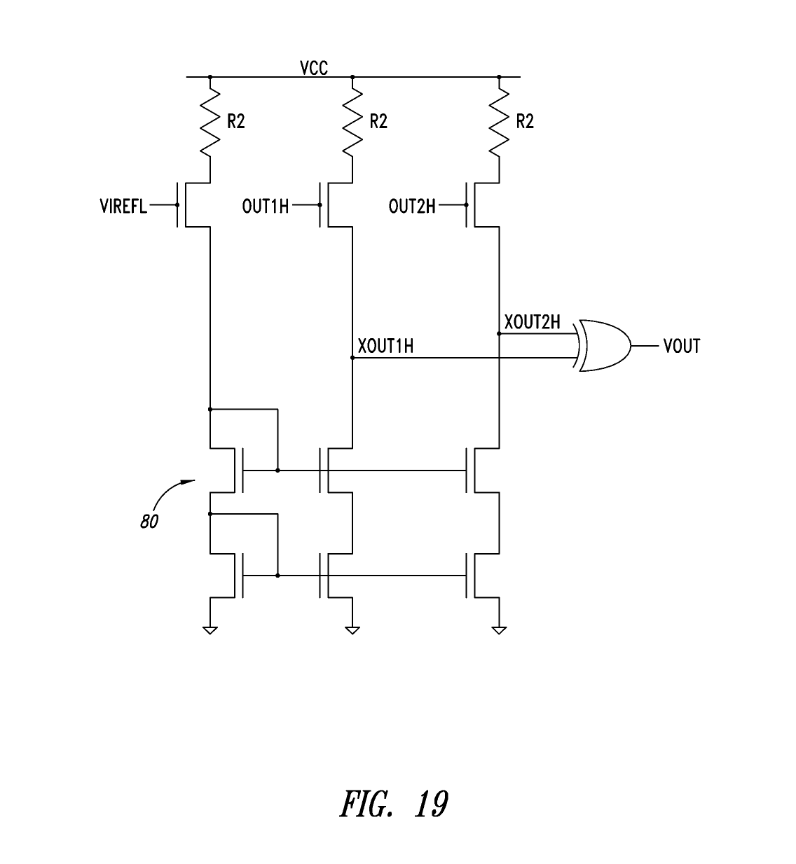

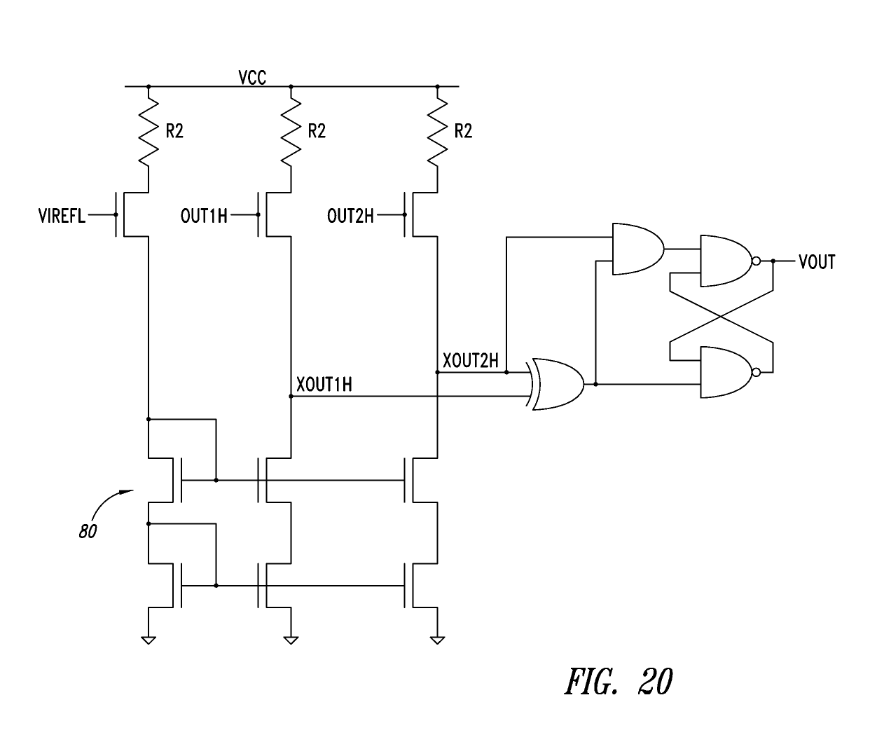

According to an embodiment depicted in FIGS. 15 and 16, that is simpler to realize but less precise than that of FIGS. 3 and 4, the control circuit 20C is substantially composed of the diode-connected transistor 21 biased by a current source 22C with a current I+ΔI different from the bias current I of each of the two branches of the input differential amplifier 10, such that the VIREFL voltage correspond to the voltage threshold with which the absolute value of the difference between the voltages VIN1 and VIN2 of the input differential pair MIN1, MIN2 is compared. In this case, the threshold is determined by establishing the current ΔI. FIG. 16 depicts an output stage 30D adapted for the architecture of FIG. 15.

Even in this case it is possible to realize corresponding architectures of “folded” topology such to work with positive and negative hysteresis and the outputs of the second stage may be combined as shown in the previous cases for realizing the different functions.

The comparator architectures of FIGS. 15 and 16 are less preferred because they are more sensitive to fluctuations of temperature and of the bias current I. It is possible to obviate this drawback by generating a variable bias current for taking into account these disturbances and for keeping the value of the hysteresis voltage the most constant as possible in the various functioning conditions.

Figures from 17 to 20 depict alternative embodiments of the output stages shown in FIGS. 4, 7, 12 and 14, respectively, comprising cascode current mirrors 80.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A comparator adapted to generate an output voltage representing a comparison of the absolute value of a difference between two input voltages with a reference voltage, comprising:
first and second input terminals configured to receive first and second input voltages, respectively;
a control voltage terminal configured to receive a control voltage;
a first differential amplifier that includes:
first and second intermediate nodes;
a first differential pair of input transistors having respective first conduction terminals, respective second conduction terminals, and respective control terminals, the control terminals of the input transistors being respectively coupled to said first and second input terminals, the second conduction terminals being respectively coupled to first and second intermediate nodes, and the first differential pair of input transistors being configured to produce first and second intermediate voltages at the first and second intermediate nodes, respectively;
a first common bias line configured to have a constant current;
a first and second degeneration resistances respectively coupling the first conduction terminals of the input transistors to the common bias line; and
an active load network that includes first and second load transistors and third and fourth degeneration resistances, the load transistors including respective control terminals coupled to the control voltage terminal and respective conduction terminals respectively coupled to the second conduction terminals of the first differential pair of input transistors by first and second intermediate nodes, respectively;
a control circuit that includes:
a diode-connected transistor having a control terminal coupled to said control voltage terminal;
a fifth degeneration resistance coupled to the diode-connected transistor; and
a circuit leg configured to force through said diode-connected transistor a current representative of said reference voltage; and
an output stage that includes a logic circuit configured to produce an output voltage as a logic combination of first and second logic signals corresponding to the first and second intermediate voltages.

2. The comparator of claim 1, wherein said control circuit comprises a second differential amplifier that includes:
first and second reference terminals configured to receive first and second differential voltages representative of the reference voltage;
a second differential pair of input transistors having respective first conduction terminals, respective second conduction terminals, and respective control terminals, the control terminals of the input transistors of the second differential pair being coupled to said first and second reference terminals, respectively,
a second common bias line configured to have a constant current substantially identical to the constant current of the first common bias line;
sixth and seventh degeneration resistances respectively coupling the first conduction terminals of the input transistors of the second differential pair to the second common bias line;
third and fourth load transistors coupled to the second conduction terminals of the input transistors of the second differential pair, the third load transistor being the diode-connected ransistor; and
an eighth degeneration resistance coupled to the fourth load transistor.

3. The comparator of claim 1, wherein said circuit leg of said control circuit is configured to force through said diode-connected transistor a current different from half of the constant current of the first common bias line of the input differential amplifier.

4. The comparator of claim 1, wherein said output stage comprises:
first and second output transistors having respective control terminals respectively coupled to said first and second intermediate nodes and configured to generate the first and second logic signals based on the first and second intermediate voltages, respectively;
a bias network configured to respectively bias said output transistors with first and second mirrored currents of the current through said diode-connected transistor of the control circuit.

5. The comparator of claim 4, wherein said output stage comprises:
a third output transistor having a control terminal coupled to said control voltage terminal; and
a current mirror coupled to said first, second, and third output transistors and configured to provide currents to the first and second output transistors based on a current through the third output transistor.

6. The comparator of claim 4, wherein said logic circuit of the output stage includes a NAND gate configured to generate said output voltage as a NAND of said first and second logic signals.

7. The comparator of claim 4, wherein said logic circuit of the output stage includes an SR latch having set and reset inputs and configured to generate said output voltage, the set input being coupled to a third intermediate node between the bias network and the first output transistor, and the reset input being coupled to a fourth intermediate node between the bias network and the second output transistor.

8. The comparator of claim 1, wherein said input differential amplifier comprises:
a first cascode transistor coupled between the first input transistor of the first differential pair and the first load transistor, the first cascode transistor including a control terminal;
a second cascode transistor coupled between a second input transistor of the first differential pair and the second load transistor, the second cascode transistor including a control terminal coupled to the control terminal of the first cascode transistor; and
a first voltage generator coupled between the control terminals of the cascode transistors and a common node of the first and second degeneration resistances, the first voltage generator being configured to establish a constant voltage between the control terminals of the first and second cascode transistors and the common node of the first and second degeneration resistances.

9. The comparator of claim 8, wherein said control circuit further comprises a second differential amplifier that includes:
first and second reference terminals configured to receive first and second differential voltages representative of the reference voltage;
a second differential pair of input transistors having respective first conduction terminals, respective second conduction terminals, and respective control terminals, the control terminals of the input transistors of the second differential pair being coupled to said first and second reference terminals, respectively,
a second common bias line configured to have a constant current substantially identical to the constant current of the first common bias line;
sixth and seventh degeneration resistances respectively coupling the first conduction terminals of the input transistors of the second differential pair to the second common bias line;
third and fourth load transistors, coupled to the second conduction terminals of the input transistors of the second differential pair, the third load transistor being the diode-connected transistor;
an eighth degeneration resistance coupled to the fourth load transistor; a third cascode transistor coupled between a first input transistor of the second differential pair and the third load transistor, the third cascode transistor including a control terminal;
a fourth cascode transistor coupled between a second input transistor of the second differential pair and the fourth load transistor, the fourth cascode transistor including a control terminal coupled to the control terminal of the third cascode transistor; and
a second voltage generator coupled between the control terminals of the third and fourth cascode transistors and a common node of the sixth and seventh degeneration resistances, the second voltage generator being configured to establish a constant voltage drop between the control terminals of the third and fourth cascode transistors and the common node of the sixth and seventh degeneration resistances.

10. The comparator of claim 1, wherein said control circuit further comprises:
a second differential amplifier that includes:
first and second reference terminals configured to receive first and second differential voltages representative of the reference voltage;
a second differential pair of input transistors having respective first conduction terminals, respective second conduction terminals, and respective control terminals, the control terminals of the input transistors of the second differential pair being coupled to said first and second reference terminals, respectively;
a second common bias line configured to have a constant current substantially identical to the constant current of the first common bias line;
sixth and seventh degeneration resistances respectively coupling the first conduction terminals of the input transistors of the second differential pair to the second common bias line;
third and fourth load transistors, coupled to the second conduction terminals of the input transistors of the second differential pair, the third load transistor being the diode-connected transistor; and
an eighth degeneration resistance coupled to the fourth load transistor; and
a third differential amplifier that includes:
third and fourth reference terminals configured to receive third and fourth differential voltages;
a third differential pair of input transistors having respective first conduction terminals, respective second conduction terminals, and respective control terminals, the control terminals of the input transistors of the third differential pair being coupled to said third and fourth reference terminals, respectively;
a third common bias line configured to have a constant current substantially identical to the constant current of the first common bias line;
ninth and tenth degeneration resistances respectively coupling the first conduction terminals of the input transistors of the third differential pair to the third common bias line; and
a pair of bias current generators coupled respectively to the second conduction terminals of the input transistors of the third differential pair and coupled respectively to the first and second intermediate nodes.

11. The comparator of claim 1, wherein said input differential amplifier has a folded architecture and said output stage comprises:
first and second output transistors having respective control terminals respectively coupled to said first and second intermediate nodes and configured to respectively generate the first and second logic signals based on the first and second intermediate voltages;
a bias network configured to respectively bias said output transistors with first and second mirrored currents of the current through said diode-connected transistor of the control circuit.

12. A method, comprising:
generating an output voltage representing a comparison between the absolute value of a difference between two input voltages with a reference voltage, the generating including:
producing first and second amplified replica voltages by amplifying said input voltages with a differential amplifier having a differential pair of input transistors and an active load network that includes first and second load transistors, the amplifying including controlling the load transistors using a same control voltage, representing said reference voltage, from a diode-connected transistor, controlled by said control voltage; and
logically combining the first and second amplified replica voltages through a logic circuit configured to generate the output voltage.

13. The method of claim 12, wherein:
producing the first and second amplified replica voltages includes:
respectively generating first and second intermediate voltages at first and second intermediate nodes coupled to respective conduction terminals of the input transistors,
controlling a first control transistor of a first leg of a current mirror using the control voltage, controlling a second control transistor of a second leg of the current mirror using the first intermediate voltage, and
controlling a third control transistor of a third leg of the current mirror using the second intermediate voltage;
the first amplified replica voltage is produced at a third intermediate node coupled to a conduction terminal of the second control transistor; and
the second amplified replica voltage is produced at a fourth intermediate node coupled to a conduction terminal of the third control transistor.

14. A comparator, comprising:
first and second input terminals configured to receive first and second input voltages, respectively;
a first differential amplifier that includes:
first and second intermediate nodes;
a first differential pair of input transistors having respective first conduction terminals, respective second conduction terminals, and respective control terminals, the control terminals of the input transistors being respectively coupled to said first and second input terminals, the second conduction terminals being respectively coupled to first and second intermediate nodes, and the first differential pair of input transistors being configured to produce first and second intermediate voltages at the first and second intermediate nodes, respectively;
first and second load transistors, the load transistors including respective control terminals and respective conduction terminals respectively coupled to the second conduction terminals of the first differential pair of input transistors by first and second intermediate nodes, respectively;
a control circuit that includes:
a diode-connected transistor having a control terminal coupled to the control terminals of the load transistors; and
a circuit leg configured to force through said diode-connected transistor a current representative of a reference voltage; and
an output stage that includes a logic circuit configured to produce an output voltage as a logical combination of first and second logical signals corresponding to the first and second intermediate voltages.

15. The comparator of claim 14, wherein said control circuit comprises a second differential amplifier that includes:
first and second reference terminals configured to receive first and second differential voltages representative of the reference voltage;
a second differential pair of input transistors having respective first conduction terminals, respective second conduction terminals, and respective control terminals, the control terminals of the input transistors of the second differential pair being coupled to said first and second reference terminals, respectively,
third and fourth load transistors coupled to the second differential pair of input transistors, whose and having respective control terminals that are coupled together, the third load transistor being the diode-connected transistor.

16. The comparator of claim 14, wherein said output stage comprises:
first and second output transistors having respective control terminals respectively coupled to said intermediate nodes and configured to generate the first and second logic signals based on the first and second intermediate voltages, respectively;
a bias network configured to respectively bias said output transistors with first and second mirrored currents of the current through said diode-connected transistor of the control circuit.

17. The comparator of claim 16, wherein said output stage comprises:
a third output transistor having a control terminal coupled to said control voltage terminal; and
a current mirror coupled to said first, second, and third output transistors and configured to provide currents to the first and second output transistors based on a current through the third output transistor.

18. The comparator of claim 16, wherein said logic circuit of the output stage includes a NAND gate configured to generate said output voltage as a NAND of said first and second logic signals.

19. The comparator of claim 16, wherein said logic circuit of the output stage includes an SR latch having set and reset inputs and configured to generate said output voltage, the set input being coupled to a third intermediate node between the bias network and the first output transistor, and the reset input being coupled to a fourth intermediate node between the bias network and the second output transistor.

20. The comparator of claim 14, wherein said input differential amplifier comprises:
a first cascode transistor coupled between the first input transistor of the first differential pair and the first load transistor, the first cascode transistor including a control terminal;
a second cascode transistor coupled between a second input transistor of the first differential pair and the second load transistor, the second cascode transistor including a control terminal coupled to the control terminal of the first cascode transistor; and
a first voltage generator coupled between the control terminals of the cascode transistors and the first conduction terminals of the first differential pair of input transistors.

21. The comparator of claim 20, wherein said control circuit further comprises a second differential amplifier that includes:
first and second reference terminals configured to receive first and second differential voltages representative of the reference voltage;
a second differential pair of input transistors having respective first conduction terminals, respective second conduction terminals, and respective control terminals, the control terminals of the input transistors of the second differential pair being coupled to said first and second reference terminals, respectively,
third and fourth load transistors coupled to the second differential pair of input transistors and having respective control terminals that are coupled together, the third load transistor being the diode-connected transistor;
a third cascode transistor coupled between a first input transistor of the second differential pair and the third load transistor, the third cascode transistor including a control terminal;
a fourth cascode transistor coupled between a second input transistor of the second differential pair and the fourth load transistor, the fourth cascode transistor including a control terminal coupled to the control terminal of the third cascode transistor; and
a second voltage generator coupled between the control terminals of the third and fourth cascode transistors and the first conduction terminals of the second differential pair of input transistors.

22. The comparator of claim 14, wherein said control circuit further comprises:
a second differential amplifier that includes:
first and second reference terminals configured to receive first and second differential voltages representative of the reference voltage;
a second differential pair of input transistors having respective first conduction terminals, respective second conduction terminals, and respective control terminals, the control terminals of the input transistors of the second differential pair being coupled to said first and second reference terminals, respectively; and
third and fourth load transistors coupled to the second differential pair of input transistors and having respective control terminals that are coupled together, the third load transistor being the diode-connected transistor; and
a third differential amplifier that includes:
third and fourth reference terminals configured to receive third and fourth differential voltages;
a third differential pair of input transistors having respective first conduction terminals, respective second conduction terminals, and respective control terminals, the control terminals of the input transistors of the third differential pair being coupled to said third and fourth reference terminals, respectively; and
a pair of bias current generators coupled respectively to the second conduction terminals of the input transistors of the third differential pair and coupled respectively to the first and second intermediate nodes.

23. The comparator of claim 14, wherein said input differential amplifier has a folded architecture and said output stage comprises:
first and second output transistors having respective control terminals respectively coupled to said first and second intermediate nodes and configured to respectively generate the first and second logic signals based on the first and second intermediate voltages;
a bias network configured to respectively bias said output transistors with first and second mirrored currents of the current through said diode-connected transistor of the control circuit.
